(19) United States
(12) Patent Application Publication
(10) Pub. No.: US 2006/0108915 A1
(43) Pub. Date: May 25, 2006

(54) Tiled OLED display

(75) Inventors: Ronald S. Cok, Rochester, NY (US); Andrew D. Arnold, Hilton, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/995,973

(22) Filed: Nov. 23, 2004

(51) Int. Cl. H01J 1/62; H01J 63/04

(52) U.S. Cl. 313/504

(57) ABSTRACT

A tiled display structure having one or more first light emitting tiles having a substrate with a first display area with spaced-apart electrodes. At least one layer of light-emitting material is provided between the spaced apart electrodes. A non-display area is provided with conductors for electrically connecting the spaced-apart electrodes in the display area to a connection point at the edge of the display substrate. The spaced apart electrodes producing light-emitting pixel elements when subjected to a current. One or more second light emitting tiles are also provided having a substrate with a second display area with spaced-apart electrodes and at least one layer of light-emitting material between the spaced apart electrodes. The second light emitting tiles are stacked above the non-display area of another tile substrate and in registration with the other first display area, the spaced apart electrodes of the second display producing light-emitting pixel elements when subjected to a current.

### FIELD OF THE INVENTION

The present invention relates to OLED flat-panel display systems composed of multiple stacked tiles.

### BACKGROUND OF THE INVENTION

Electronic display systems are commonly used to display information from computers. Typical display systems range in size from small displays used in mobile devices to very large displays visible to thousands of viewers. Large displays are sometimes created from tiling smaller display devices together. For example, video walls using multiple video displays are frequently seen in the electronic media and flat-panel displays are tiled to create larger displays. Multiple projector systems used to create a large, tiled, high-resolution display are also available.

Tiled displays are well known in the prior art. For example, U.S. Pat. No. 6,683,665B1 issued Jan. 27, 2004 describes tile structures wherein each tile has a display portion and an electronics portion. The tiles are fastened together into an array with the use of a frame. Alternatively, U.S. Pat. No. 6,498,592 issued Dec. 24, 2002 describes the use of a single substrate with electrical devices and a display. However, as disclosed, these designs require the use of vias through the electronics substrates and are problematic for displays requiring a hermetic seal for the display components, for example in an OLED display. Vias in glass substrates are difficult to construct and the use of alternative substrates are not well suited to sealing the display materials. Moreover, the design requires an additional frame and is not well suited to roll-to-roll manufacturing.

Another technique that relies on overlapping the display tiles is described in WO 03/042966 published May 22, 2003 entitled “Display for a Large Panel Display Consisting of Tiled Displays”. This method uses a complex support structure and a plurality of printed circuit boards. Moreover, tile seams may be visible when the display is viewed off angle.

There is a need therefore for an improved tiled display system that overcomes the problems noted above.

### SUMMARY OF THE INVENTION

In accordance with one aspect of the present invention there is provided a tiled OLED display structure, comprising:

a) one or more first OLED tiles having a substrate with a first display area with spaced-apart electrodes and at least one layer of organic light-emitting material between the spaced apart electrodes and a non-display area with conductors for electrically connecting the spaced-apart electrodes in the display area to a connection point at the edge of the display substrate, the spaced apart electrodes producing light-emitting pixel elements when subjected to a current; and

b) one or more second OLED tiles having a substrate with a second display area with spaced-apart electrodes and at least one layer of organic light-emitting material between the spaced apart electrodes stacked above the non-display area of another OLED tile substrate and in registration with the other first display area, the spaced apart electrodes of the second display area producing light-emitting pixel elements when subjected to a current.

In accordance with another aspect of the present invention there is provided a tiled display structure, comprising:

a) one or more first light emitting tiles having a substrate with a first display area with spaced-apart electrodes and at least one layer of light-emitting material between the spaced apart electrodes and a non-display area with conductors for electrically connecting the spaced-apart electrodes in the display area to a connection point at the edge of the display substrate, the spaced apart electrodes producing light-emitting pixel elements when subjected to a current; and

b) one or more second light emitting tiles having a substrate with a second display area with spaced-apart electrodes and at least one layer of light-emitting material between the spaced apart electrodes stacked above the non-display area of another tile substrate and in registration with the other first display area, the spaced apart electrodes of the second display producing light-emitting pixel elements when subjected to a current.

### ADVANTAGES

The present invention has the advantage that the tiled display utilizes very simple electrical interconnections, does not require substrate vias, is simple to manufacture in a continuous process, and has improved yields.

These and other aspects, objects, features and advantages of the present invention will be more clearly understood and appreciated from a review of the following detailed description of the preferred embodiments and appended claims and by reference to the accompanying drawings.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1a is a perspective view of a display substrate with a plurality of registered display area/tiles of FIG. 1b affixed to the display substrate according to an embodiment of the present invention;

FIG. 1b is a perspective view of a single display area according to one embodiment of the present invention on a supporting substrate;

FIG. 2a is a perspective view of the display substrate of FIG. 1a wherein a second layer of display areas/tiles is proviced;

FIG. 2b is an enlarged partial top view of FIG. 2a as illustrated by circle 26;

FIG. 3 is a perspective view of a display substrate of FIG. 2a with support tiles which are affixed to the display substrate;

FIG. 4 is a perspective view of a display substrate of FIG. 3 with registered display areas/tiles located over support substrates; and

FIG. 5 is a perspective view of FIG. 4 in the next step of making a 16-tile display according to an embodiment of the present invention.

The layers of the Figures are not to scale, since the differences in size of the elements in the Figures are too great to permit depiction at scale.

### DETAILED DESCRIPTION OF THE INVENTION

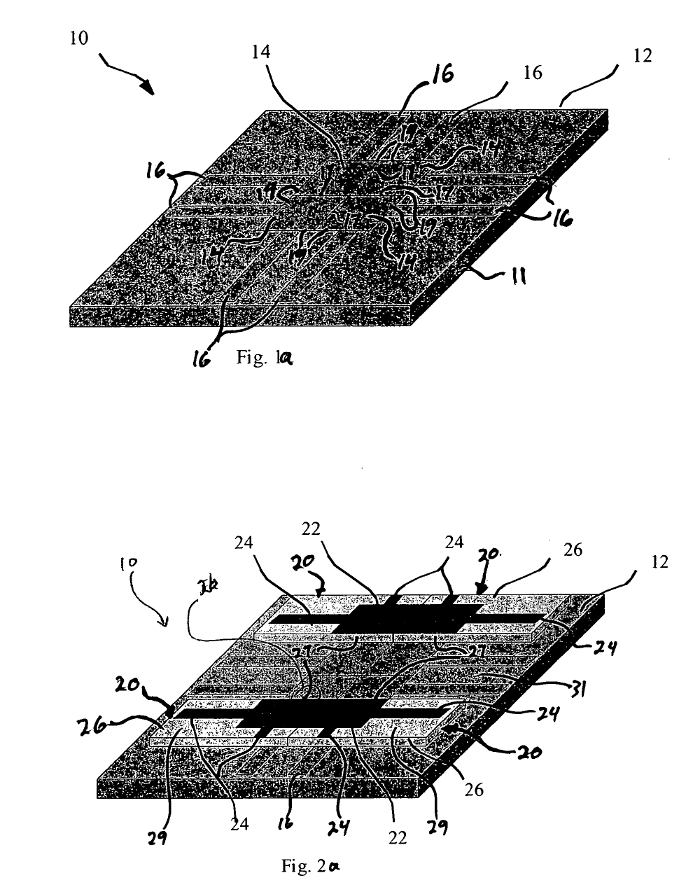

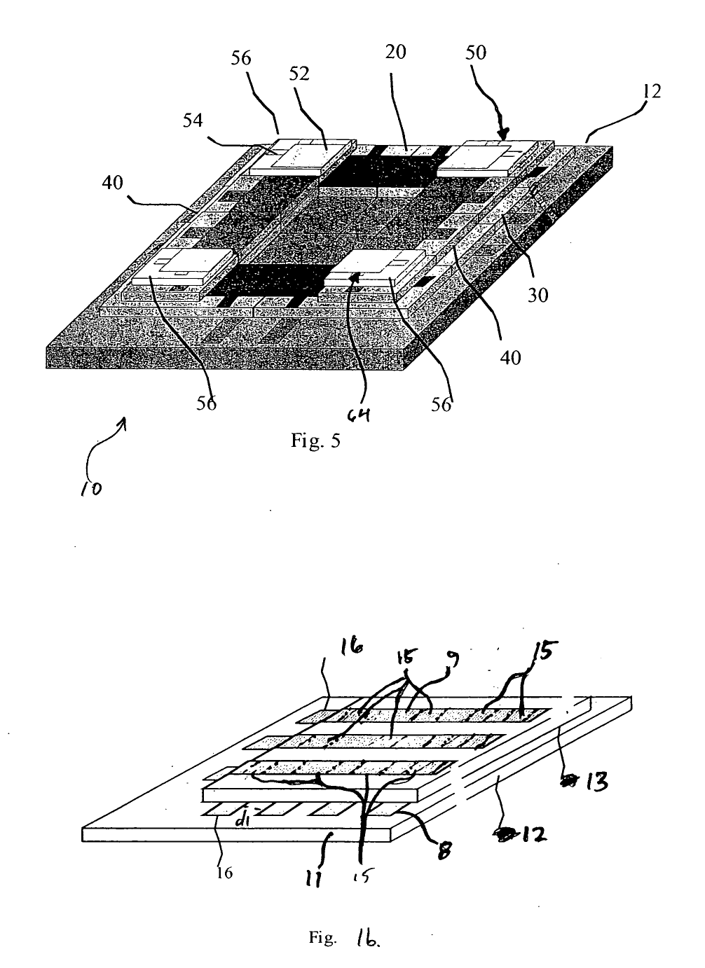

Referring to FIGS. 1a and 1b there is illustrated the first steps in making a display structure 10 in accordance with the present invention. In the embodiment illustrated, the display structure 10 comprises an OLED (organic light emitting diode), however the present invention is not so limited, the structure 10 may comprise a LED (light emitting diode) or a LCD (liquid crystal display). The first step in constructing display structure 10 is providing a supporting substrate 12. The substrate 12 may be made of any appropriate material and of an appropriate structure. The substrate 12 may rigid or flexible and may comprise glass, metal, plastic, flexible glass, or flexible metal foil. In one embodiment, a plurality of first electrodes 8, is first deposited on the substrate 12. Light-emitting materials 13 are deposited over the plurality of first electrodes 8 and may comprise, for example, multiple layers of organic materials including hole-injection, hole-transporting, light-emitting, electron-transporting, and electron-injection layers. These layers may be formed and deposited upon the substrate 12 using methods well-known in the art, for example using evaporative means or coating means such as spin or curtain coating to form rectangular display areas 14 on substrate 12. One or more second electrodes 9 are formed over the light-emitting materials 13. The first and second electrodes 8, 9 are electrically connected to conductors 16 that extend near to the edge 11 of the substrate 12 where they are accessible to external connections, for example with electrical cables including wires for providing signals and power. The control for the light-emitting materials 13 may be passive-matrix control drivers connected to the conductors and electrodes (not shown). Alternatively, active-matrix devices may be used but are more difficult to register due to the increased number of electrical components formed on the substrate. Light-emitting pixel elements 15 (indicated by dash lines) are created where the first and second electrodes 8, 9 overlap and conduct electrical current through the light-emitting materials 13.

As shown in FIG. 1a, four rectangular display areas 14 contiguous on two sides 17 of each area 14 are formed over the substrate 12 with separate electrodes 8, 9 (see FIG. 1b,) connected by conductors 16 on the remaining two sides 19 of each display area 14. Separate controllers and electrical connections may thus be provided for each display area 14. As is well known, passive-matrix displays are simply and inexpensively manufactured in comparison to active-matrix displays because they do not require the manufacture of active electronic components on the substrate 12. However, passive-matrix displays are generally limited in size, due to the increasing burden of connectors and lengthy connections as the displays grow larger. The present invention overcomes these limitations by using a tiled structure. By employing separate controllers and connections to each display area 14, the present invention reduces the number and size of connections to each display area and enables larger displays, in particular passive-matrix displays, than would otherwise be practicable.

The display 10 may be encapsulated with a single encapsulating cover (not shown) affixed with an adhesive to the display substrate 12. Alternatively, each OLED display tile may be separately encapsulated with its own cover. In either case, allowance must be made for the conductors or any connecting cables to pass under or through the cover. Preferably, the encapsulating cover(s) are very thin to minimize the thickness of the overall display. In particular, coated encapsulating covers comprising a thin, conformal coating located over the top spaced-apart electrode are preferred.

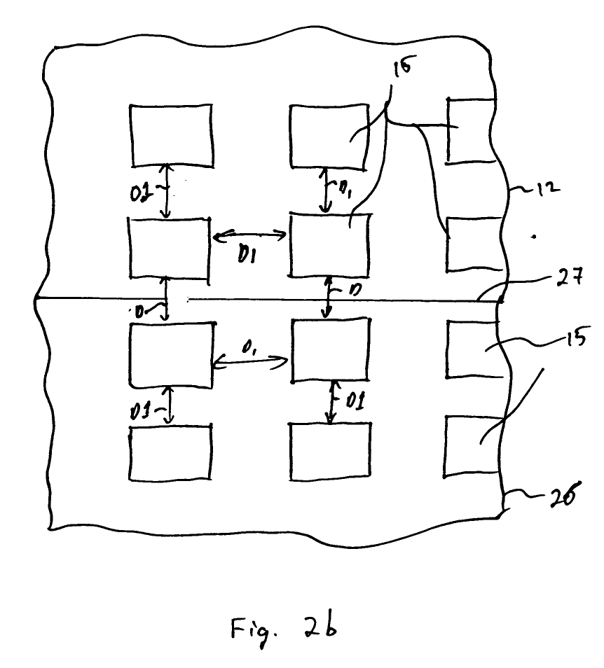

The next step in the manufacture of display 10 is illustrated by FIG. 2a, wherein four display tiles 20 are stacked on substrate 12, each display tile 20 comprising a tile substrate 26 having a display area 22, and electrode conductors 24. Thus, the display areas 22 of display tile 20 are above non-display areas of tile substrate 12. The display area 22 and electrode conductors 24 are substantially identical to display areas 14 and conductors 16, like numeral representing like parts and operation formed on the display substrate 12. However, the tiles 20 are smaller than the display substrate 12, and extend from the top and bottom edges of the display areas 14 to the top and bottom edge of the display substrate 12. The display areas 22 on the substrate 26 are formed near the edge 27 of the substrate 26 and the pixels 15 formed by the electrodes 8, 9 have the same size and pitch as the pixels 15 formed by the electrodes 8, 9 on the display substrate 12. Additional non-display area space 31 is provided on the tile substrate 12 for subsequent support substrates 30. As is well understood in tiled displays, the distance D between the pixels 15 adjacent the edges 27 of the display areas 14 and 22 on the tile substrates 12 and 26, respectively, must be equal to the inter-pixel distance D1 on each of the substrates 12, 26. Hence, the pixels 15 appear to be uniform across the display areas 14 and 22. The tile substrate 26 should be as thin as practicable and preferably less than 500 microns in thickness so as to maintain the uniformity of the display when viewed at large angles. In particular, the thickness of the tile substrate 26 should be small relative to the size of the pixels 15. For example, a large display may have 3 mm pixels 15 with 0.5 mm gaps G between adjacent pixels 15. A transparent tile substrate 26 is also useful in reducing non-uniformities in the display when viewed at large angles by permitting light to pass light from the pixels on the displays substrate 12 through the tile substrate 26.

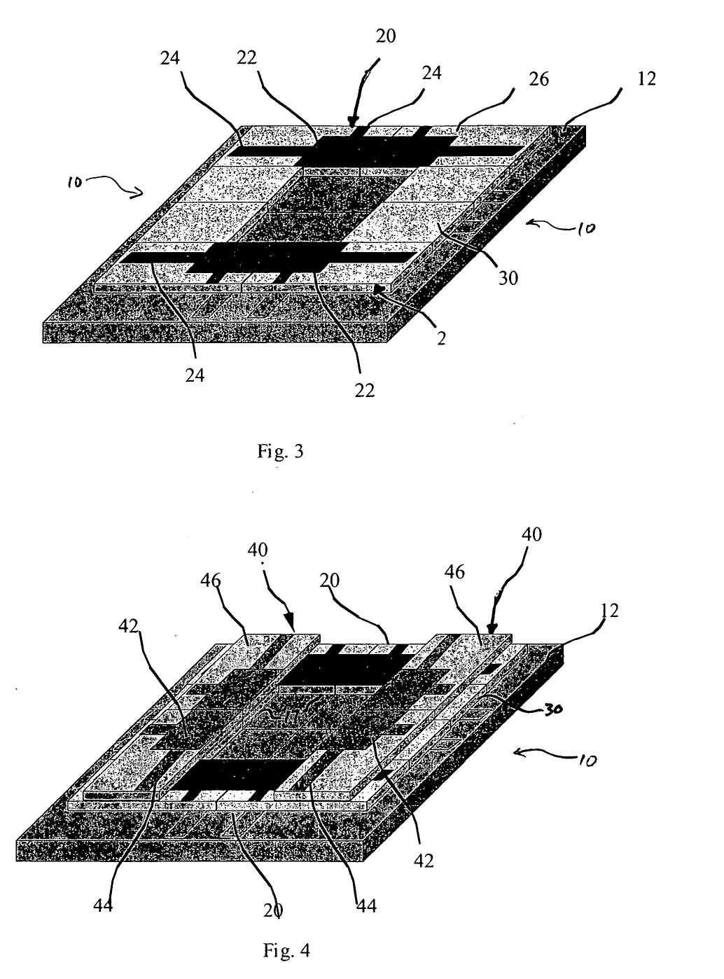

Referring to FIG. 3 the next step of making display structure 10 is illustrated. A support substrate 30 is positioned in the open space 31 adjacent to the OLED tiles 20 above the display substrate 12 to form an open rectangle surrounding the display area 14. The support substrates 30 simply serve to fill in the space 31 to support the OLED tiles located in the next layer.

Referring to FIG. 4, a second layer of OLED tiles 40 are located (stacked) above the substrate 30 and OLED tiles 20. The display areas 42 of OLED tiles 40 are registered with the edges 17 of the display areas 14 and its pixel size and pitch are identical with those in the other display areas 14 and 22. The OLED tiles 40 are constructed on a substrate 46 with electrode conductors 44 that are similar to the conductors 24 of OLED tiles 20.

Referring to FIG. 5, a third layer of OLED tiles 50 having display areas 52 are located and aligned in registration above the non-display areas of the OLED tiles 20 at each corner of the display substrate 46 to form a contiguous, uniform, rectangular display area 64 having 16 display areas 14, 22, 42, 52. The OLED tiles 50 are constructed on a substrate 56 with conductors 54 that are similar to the conductors 24 and 44 of OLED tiles 20 and 40 respectively.

The electrodes 16, 24, 44, and 54 all extend beyond the edges of tile layers so that space is provided for connecting electrical cables to the electrodes. Alternatively, drivers themselves may be located on the edges of the tiles. Each OLED tile 20, 40, 50, and the display areas 14, 22, 42, 52 on the display substrates may be driven identically and separately, thereby enabling larger displays. Each OLED tile 20, 40, and 50 may be separately encapsulated with a cover as is known in the art or the entire display structure 10 may be encapsulated under one larger cover.

The substrates 20 and 40 have a similar size, although the orientation of half of the substrates is a mirror image of the other half of the substrates. This similar size and symmetry reduces manufacturing costs. The substrates 46 must be slightly smaller than the substrate 26 to allow the conductors 24 to extend beyond the substrate 46 to allow connectors to be connected to a controller. Likewise, the support tiles 30 have a similar size to the OLED tiles 50, although the OLED tile 50 must be slightly smaller in one dimension than the substrate 46 to allow the conductors 44 to extend beyond the substrate 56.

The display areas 14, 22, 42, and 52 are identical and may be constructed using common deposition and masking techniques, as are well known in the OLED art. Each OLED tile may be tested individually before assembly onto the display substrate 12, thereby improving yields in the final, assembled display.

In operation, power is provided by controllers (not shown) through the electrodes 16, 24, 44, and 54 to cause a current to flow through the OLED materials in the pixels 15 of the display area of each tile. The current causes each pixel 15 to light up as controlled. The control and operation of OLED devices is well known in the art.

The present invention has been described in an embodiment including 16 tiles in a four-by-four array. Other arrangements are possible. For example, a three-by-three array can be formed by locating a single central display area 14 in the center of a display substrate 12, positioning four identical OLED tiles 20 around the periphery of, and in registration with, the display area 24 on the display substrate 26. Four corner tiles 50 can be located above the non-display areas of OLED tiles 20 to form a complete, rectangular array. Likewise, larger displays of, for example, 25 tiles in a five-by-five array may be made. In each arrangement, successive stacked layers of OLED tiles with support tiles positioned between them as necessary can form a contiguous array 64 of display areas.

Because of the stacked tile arrangement, the display substrate 12 may be very large, for example, a square meter or larger. In an alternative embodiment it is possible to locate an initial OLED tile over the center of the display substrate 12 so that OLED materials and electrodes do not need to be deposited on the display substrate. For example, an OLED tile of one quarter the size of the display substrate 12 may be positioned on each quadrant of the display substrate to form a support for subsequent layers of OLED tiles and support tiles.

Alternatively, the support tiles may be integrated into the OLED tiles so that the tile substrate is larger than shown. In this case, the non-display areas are located over underlying display areas.

The present invention may be manufactured in a continuous manufacturing process wherein the display and tile substrates are made on a continuous web. Once manufactured, the substrates may be singulated and assembled. The use of a stacked tile structure removes any need for vias in a substrate or connections between tiles, thereby improving encapsulation, improving reliability, and reducing costs of manufacturing.

In a preferred embodiment, the present invention is employed in a tiled flat-panel array of OLED display devices composed of small molecule or polymeric OLEDs as disclosed in but not limited to U.S. Pat. No. 4,769,292, issued Sep. 6, 1988 to Tang et al., and U.S. Pat. No. 5,061,569, issued Oct. 29, 1991 to VanSlyke et al. Many combinations and variations of organic light-emitting displays can be used to fabricate such a device.

The invention has been described in detail with particular reference to certain preferred embodiments thereof, but it will be understood that variations and modifications can be effected within the spirit and scope of the invention.

### PARTS LIST

8 first electrodes
9 second electrodes
10 tiled display
11 edge
12 display substrate
13 light emitting materials
14 display area
15 pixels
16 conductors
17 sides
19 sides
20 tile
22 display area
24 conductors
26 tile substrate
27 edge
30 support substrate
31 area space
41 tile
42 display area
44 conductors
46 tile substrate
50 tile
52 display area
54 conductors
56 tile substrate
64 display area

What is claimed is:

1. A tiled OLED display structure, comprising:
a) one or more first OLED tiles having a substrate with a first display area with spaced-apart electrodes and at least one layer of organic light-emitting material between the spaced apart electrodes and a non-display area with conductors for electrically connecting the spaced-apart electrodes in the display area to a connection point at the edge of the display substrate, said spaced apart electrodes producing light-emitting pixel elements when subjected to a current; and
b) one or more second OLED tiles having a substrate with a second display area with spaced-apart electrodes and at least one layer of organic light-emitting material between the spaced apart electrodes stacked above the non-display area of another OLED tile substrate and in registration with the other first display area, said spaced apart electrodes of said second display area producing light-emitting pixel elements when subjected to a current.

2. The tiled OLED display structure claimed in claim 1 comprising:
a) a display substrate having one or more display areas and a non-display area;
b) one or more OLED display tiles, located over the display substrate and having a display area adjacent to and in registration with the display area on the display substrate;
c) one or more support tiles, each support tile located over a non-display area on the display substrate and adjacent to one or more OLED display tiles;
d) one or more OLED display tiles located over a support tile and having a display area in registration with the display areas of adjacent OLED display tiles.

3. The OLED display structure claimed in claim 1 wherein the display tiles are passive-matrix displays.

4. The OLED display structure claimed in claim 1 wherein one of the spaced-apart electrodes is transparent.

5. The OLED display structure claimed in claim 1 further comprising one or more electrical connectors connected to the conductors of each OLED display tile.

6. The OLED display structure claimed in claim 1 wherein the substrate of an OLED tile protrudes beyond the substrate of an OLED tile above it.

7. The OLED display structure claimed in claim 1 wherein the light-emitting materials are organic light emitting materials.

8. The OLED display structure claimed in claim 1 wherein the light-emitting materials comprise one or more layers of organic materials.

9. The OLED display structure claimed in claim 8 wherein the light-emitting materials further comprise layers of materials including one or more layers of hole-injection material, hole-transport material, emissive material, electron-injection material, and electron-transport material.

10. The OLED display structure claimed in claim 1 wherein the OLED display tile and support tile substrates are affixed with an adhesive.

11. The OLED display structure claimed in claim 1 further comprising a separate encapsulating cover located over each of the OLED display tiles and affixed to the OLED display tile substrate.

12. The OLED display structure claimed in claim 1 wherein the encapsulating cover is a layer located over the spaced-apart electrodes.

13. The OLED display structure claimed in claim 2 further comprising an encapsulating cover located over all of the OLED display tiles and the support tiles and affixed to the display substrate.

14. A tiled display structure comprising:
a) one or more first light emitting tiles having a substrate with a first display area with spaced-apart electrodes and at least one layer of light-emitting material between the spaced apart electrodes and a non-display area with conductors for electrically connecting the spaced-apart electrodes in the display area to a connection point at the edge of the display substrate, said spaced apart electrodes producing light-emitting pixel elements when subjected to a current; and
b) one or more second light emitting tiles having a substrate with a second display area with spaced-apart electrodes and at least one layer of light-emitting material between the spaced apart electrodes stacked above the non-display area of another tile substrate and in registration with the other first display area, said spaced apart electrodes of said second display producing light-emitting pixel elements when subjected to a current.

15. The tiled display structure claimed in claim 14 comprising:
a) a display substrate having one or more display areas and a non-display areas;
b) one or more display tiles, located over the display substrate and having a display area adjacent to and in registration with the display area on the display substrate;
c) one or more support tiles, each support tile located over a non-display area on the display substrate and adjacent to one or more display tiles;
d) one or more display tiles located over a support tile and having a display area in registration with the display areas of adjacent display tiles.

16. The display structure claimed in claim 14 wherein the display tiles are passive-matrix displays.

17. The display structure claimed in claim 14 wherein one of the spaced-apart electrodes is transparent.

18. The display structure claimed in claim 14 further comprising one or more electrical connectors connected to the conductors of each OLED display tile.

19. The display structure claimed in claim 14 wherein the substrate of a tile protrudes beyond the substrate of a tile above it.

20. The display structure claimed in claim 14 wherein the light-emitting materials are organic light emitting materials.

21. The display structure claimed in claim 14 wherein the light-emitting materials comprise one or more layers of organic materials.

22. The display structure claimed in claim 21 wherein the light-emitting materials further comprise layers of materials including one or more layers of hole-injection material, hole-transport material, emissive material, electron-injection material, and electron-transport material.

23. The display structure claimed in claim 14 wherein the display tile and support tile substrates are affixed with an adhesive.

24. The display structure claimed in claim 14 further comprising a separate encapsulating cover located over each of the display tiles and affixed to the display tile substrate.

25. The display structure claimed in claim 24 wherein the encapsulating cover is a layer located over the spaced-apart electrodes.

26. The display structure claimed in claim 15 further comprising an encapsulating cover located over all of the display tiles and the support tiles and affixed to the display substrate.
